(19) United States
(12) Patent Application Publication
(10) Pub. No.: US 2007/0064496 A1
(43) Pub. Date: Mar. 22, 2007

(54) Cell string of flash memory device and method of manufacturing the same

(75) Inventor: Sang Hyun Oh, Anyang-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/484,437

(22) Filed: Jul. 11, 2006

(30) Foreign Application Priority Data
Sep. 20, 2005 (KR) 2005-87444

(51) Int. Cl. G11C 16/04

(52) U.S. Cl. 365/185.29

(57) ABSTRACT

Disclosed herein are a cell string of a flash memory device and a method of manufacturing the same. The cell string of a flash memory device includes a plurality of memory cells connected to a single bit line and arranged with first distance between the memory cells, and a source select transistor connected to a common source region and having the second distance between the source select transistor and the first memory cell of the plurality of memory cells. The second distance is greater than the first distance and less than three times of the first distance.

### BACKGROUND

1. Field of the Invention

The present invention relates to a semiconductor device and a method of manufacturing the same, and more particularly, to a cell string of a flash memory device and a method of manufacturing the same.

2. Discussion of Related Art

In a NAND flash memory device, a program disturb phenomenon exists in which cells that are not selected during the program operation of the NAND flash memory device is programmed. This major problem lowers the speed of the NAND flash memory device. Accordingly, there is a need for a solution to this problem.

As shown in FIG. 1, the cell string of the NAND flash memory in the related art includes a source select transistor SSL having a common source CS, a drain select transistor (not shown) having a drain connected to a bit line, and flash memory cells MC0 to MC15 or MC31 connected in series between the source select transistor SSL and the drain select transistor (not shown). 16 or 32 flash memory cells MC0 to MC15 or MC31 may be formed in series between the source select transistor SSL and the drain select transistor (not shown). Each of the flash memory cells MC0 to MC15 or MC31 share a junction.

However, due to the higher integration of the devices, the distance A between the first memory cell MC0 and the source select transistor SSL becomes gradually narrower in the string structure. This generates a dramatic program disturb phenomenon during the program operation of the NAND flash memory device.

The dramatic program disturb phenomenon are generated at the memory cell adjacent to the source select transistor since the boosting level of the memory cell becomes high due to hot carriers generated at the edges of the source select transistor.

Accordingly, there is a need for techniques to prevent the program disturb phenomenon that occurs during the program operation of the NAND flash memory device.

### SUMMARY OF THE INVENTION

An embodiment of the present invention provides a cell string of a flash memory device and a method of manufacturing the same, in which the program disturb phenomenon can be prevented during the program operation of a NAND flash memory device.

A cell string of a flash memory device according to an embodiment of the present invention includes a plurality of memory cells connected to a single bit line and arranged with first distance between the memory cells, and a source select transistor connected to a common source region and having the second distance between the source select transistor and a first memory cell of the plurality of memory cells. The second distance is greater than the first distance and is less than three times of the first memory cell.

The width of the gate of the source select transistor may be 1 to 2 times greater than the width of the gate of the memory cells.

A method of manufacturing a cell string of a flash memory device according to embodiment of the present invention includes the steps of: providing a semiconductor substrate including layered films for a gate electrode; etching the films for the gate electrode to form a plurality of memory cells and a pattern for forming source select transistor; forming an interlayer insulating film on the entire structure including the memory cells and the pattern; forming a source contact hole and first and second source select transistors by etching a predetermined region of the pattern to expose a given region of the semiconductor substrate; forming a spacer film on sidewalls of the source contact hole; and, forming a conductive film within the source contact hole, thereby forming a source contact plug.

The distance between the first memory cell of the plurality of memory cells and the pattern may be greater than the distance between the memory cells and less than three times of the distance between the memory cells.

The width of the gate of the source select transistor may be 1 to 3 times greater than the width of the gate of the memory cells.

The semiconductor substrate includes layered films for the gate electrode, and the films may include a tunnel oxide film, a conductive film for a floating gate, a dielectric film, and a conductive film for a control gate.

The method further includes the step of performing a first ion implantation process to form first junction regions in the semiconductor substrate between adjacent memory cells and between the first memory cell and the pattern, after the plurality of memory cells are formed and the pattern is formed.

The method may further include the step of performing a second ion implantation process to form a second junction region in the semiconductor substrate between the first and second source select transistors, after the source contact hole is formed.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view illustrating the cell string structure of the flash memory device in the related art; and

FIGS. 2 to 6 are cross-sectional views illustrating a method of manufacturing a cell string of a flash memory device according to an embodiment of the present invention.

### DETAILED DESCRIPTION OF THE EMBODIMENTS

The present invention will now be described in detail in connection with certain exemplary embodiments with reference to the accompanying drawings. To clarify multiple layers and regions, the thickness of the layers is enlarged in the drawings. Like reference numerals designate like elements throughout the specification. Furthermore, when it is said that any part, such as a layer, film, area, or plate, is positioned on another part, then the part is directly on the other part or above the other part with at least one intermediate part. On the other hand, if any part is said to be positioned directly on another part, then there is no intermediate part between the two parts.

FIGS. 2 to 6 are cross-sectional views illustrating a method of manufacturing a cell string of a flash memory device according to an embodiment of the present invention.

Referring to FIG. 2, a tunnel oxide film 12, a first conductive film 14 for a floating gate, an oxide-nitride-oxide (“ONO”) film 16 (i.e., a dielectric film), a second conductive film 18 for a control gate, and a hard mask (not shown) are sequentially formed on a semiconductor substrate 10.

A photoresist pattern (not shown) is then formed on given regions of the hard mask. An etching step is performed using the photoresist pattern (not shown) as an etch mask, thus forming a drain select transistor (not shown), a pattern SST for a source select transistor, and flash memory cells MC0 to MCn-1 formed in series between a drain select transistor and the pattern SST.

Thereafter, an ion implantation process is performed on the resulting surface, forming first junction regions S1 between flash memory cells and the pattern SST and between the flash memory cells and the drain select transistor.

A first source select transistor SSL1 and a second source select transistor SSL2, and a source contact hole SCH are defined in the pattern SST through subsequent processes as shown in FIG. 4.

The pattern SST and the first memory cell MC0 are separated by a predetermined distance A+B. Through these processes, the pattern SST becomes the first and second source select transistors SSL1, SSL2. Accordingly, the predetermined distance A+B becomes the distance between the source select transistor and the first memory cell MC0.

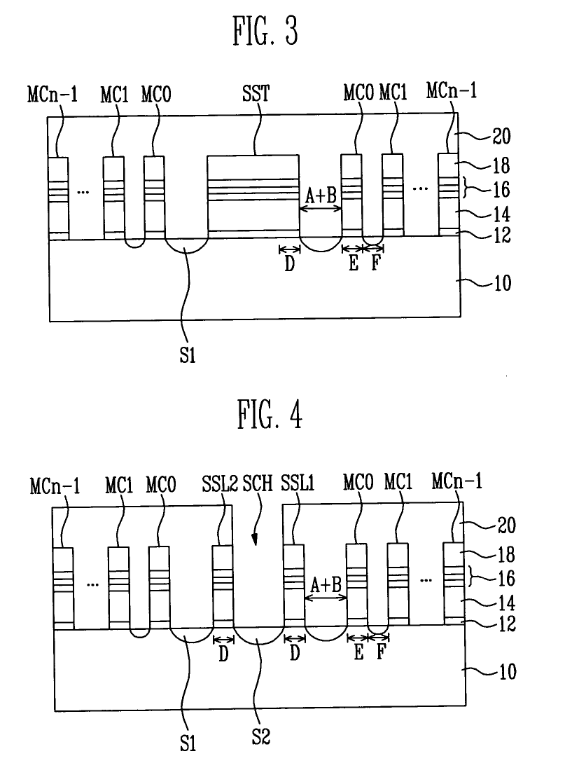

Referring to FIG. 3, an interlayer insulating film 20 is formed on the resulting structure in which the drain select transistor, the pattern SST, and the flash memory cells MC0 to MCn-1 are formed.

Referring to FIG. 4, to expose a portion of the semiconductor substrate under of the pattern SST, a photoresist pattern (not shown) is formed on the interlayer insulating film 20. An etching step is performed using the photoresist pattern as an etch mask, thereby exposing a predetermined region of the semiconductor substrate (i.e., a region in which a common source will be formed). As a result, the common source contact hole SCH is formed. At the same time, the first and second source select transistors SSL1, SSL2 are formed. Accordingly, the present invention can form gates for the first and second source select transistors SSL1, SSL2 having a desired width.

Thereafter, an ion implantation process is performed on the resulting surface to form a second junction region S2 between the first source select transistor SSL1 and the second source select transistor SSL2.

The second junction region S2 is the common source region of the source select transistors SSL1, SSL2.

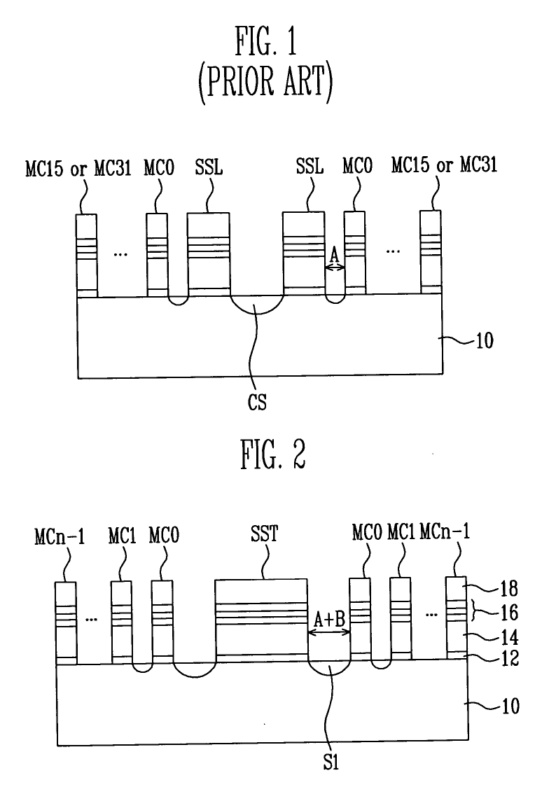

In the pattern SST, the first and second source select transistors SSL1, SSL2 and the common source contact hole SCH are defined through the etching step. The width D of the gates of the first and second source select transistors SSL1, SSL2 is selected to be less than the width C of the gate of the source select transistor SSL shown in FIG. 1. As a result, due to the narrowed width of the gates of the source select transistors SSL1, SSL2, the distance A+B between the source select transistors SSL1, SSL2 and the first memory cell MC0 can be increased compared to the related art.

In other words, the distance A+B between the source select transistors SSL1, SSL2 and the first memory cell MC0 according to an embodiment of the present invention is selected to be greater than the distance A between the source select transistor SSL and the first memory cell MC0 in the related art.

Referring to FIG. 5, a film (not shown) for spacers is formed on the resulting surface in which the common source contact hole SCH is formed. An etch-back process is then performed to form spacers 22 on the sidewalls of the common source contact hole SCH.

The spacers 22 function to prevent the short between the source select transistors SSL1, SSL2 and a common source contact, which will be formed subsequently.

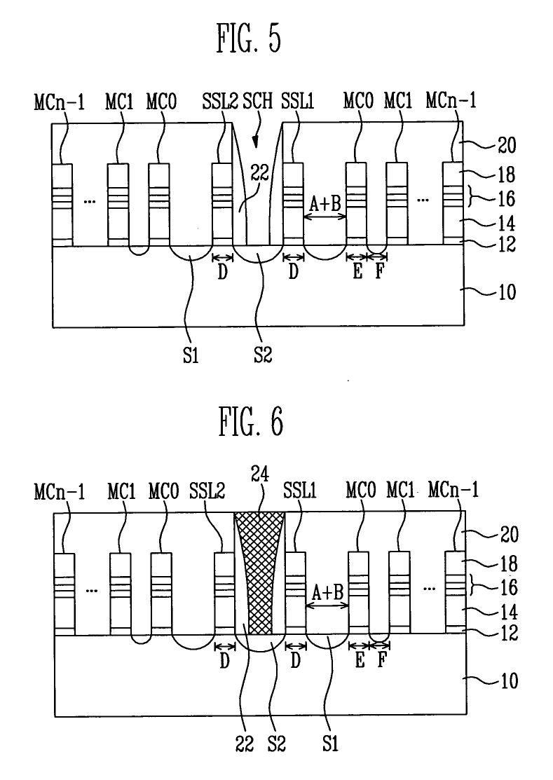

Referring to FIG. 6, a conductive material is formed on the resulting structure in which the spacers 22 are formed. A polishing process, such as chemical-mechanical polishing (“CMP”) process, is performed until the interlayer insulating film is exposed, thereby forming the common source contact 24.

Meanwhile, the distance A+B between the source select transistors SSL1, SSL2 and the first memory cell MC0 may be selected to be greater than the distance between adjacent memory cells, as illustrated, for example, by the distance F between the first memory cell MC0 and the second memory cell MC1.

Furthermore, the width D of the gate of the source select transistors SSL1, SSL2 may be selected to be from 1 to 3 times greater than the width E of the gate of the memory cells MC0 to MC31.

In addition, the distance A+B may be selected to be greater than the distance F between adjacent memory cells and to be less than three times of the distance F.

The completed cell string structure of the flash memory device includes the plurality of memory cells MC0 to MC31 connected to a single bit line (not shown) and arranged with first distance between the memory cells. The completed cell string structure of the flash memory device also includes the source select transistors SSL1, SSL2, connected to the common source region S2 and having the second distance between the source select transistor and the first memory cells MC0 of the plurality of memory cells. The second distance is greater than the first distance and less than three times of the first distance.

Furthermore, the distance A+B may be selected to be greater than the distance F between the memory cells. The width D of the gate of the source select transistors SSL1, SSL2 may be 1 to 3 times greater than the width E of the gate of the memory cells.

In accordance with the present invention, the distance A+B is selected to be greater than the width A between the source select transistor SSL and the first memory cell MC0 in the related art. Accordingly, the dramatic program disturb phenomenon can be prevented during the program operation of the NAND flash memory device. Also, the present invention can form a gate of the source select transistor having a desired width and prevent the short between the source select transistors and the common source contact so that stability of the device can be secured.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A cell string of a flash memory device, comprising:
a plurality of memory cells connected to a single bit line of the flash memory device, said memory cells being arranged with a first distance between the memory cells; and
a source select transistor connected to a common source region of the flash memory device and having a second distance between the source select transistor and the first memory cell of the plurality of memory cells,
wherein the second distance is greater than the first distance and less than three times of the first distance.

2. The cell string of claim 1, wherein the width of the gate of the source select transistor is 1 to 3 times greater than the width of the gate of the memory cells.

3. A method of manufacturing a cell string of a flash memory device, the method comprising the steps of:
providing a semiconductor substrate comprising layered films for a gate electrode;
etching the films for the gate electrode to form a plurality of memory cells and a pattern for forming a source select transistor;
forming an interlayer insulating film on the entire structure including the memory cells and the pattern;
forming a source contact hole and first and second source select transistors by etching a predetermined region of the pattern to expose a given region of the semiconductor substrate;
forming a spacer film on sidewalls of the source contact hole; and
forming a conductive film within the source contact hole, thereby forming a source contact plug.

4. The method of claim 3, wherein the distance between the first memory cell of the plurality of memory cells and the pattern is greater than the distance between the memory cells and less than three times of the distance between the memory cells.

5. The method of claim 3, wherein the width of the gate of the source select transistor is 1 to 3 times greater than the width of the gate of the memory cells.

6. The method of claim 3, wherein the films for the gate electrode comprise a tunnel oxide film, a conductive film for a floating gate, a dielectric film, and a conductive film for a control gate.

7. The method of claim 3, further comprising the step of performing a first ion implantation process to form first junction regions in the semiconductor substrate between adjacent memory cells and between the first memory cell and the pattern, after the plurality of memory cells are formed and the pattern is formed.

8. The method of claim 3, further comprising the step of performing a second ion implantation process to form a second junction region in the semiconductor substrate between the first and second source select transistors, after the source contact hole is formed.
